(19) United States
(12) Patent Application Publication
(10) Pub. No.: US 2003/0201164 A1
(43) Pub. Date: Oct. 30, 2003

(54) Method of making electrically conductive, IR transparent metal oxide films

(76) Inventors: Linda F. Johnson, Ridgecrest, CA (US); Mark B. Moran, Ridgecrest, CA (US)

Correspondence Address: NAVAIRWD, COUNSEL GROUP (CODE K0000D), 1 ADMINISTRATION CIRCLE, CHINA LAKE, CA, 93555-6100, US

(21) Appl. No.: 10/133,862

(22) Filed: Apr. 29, 2002

(51) Int. Cl. C23C 14/32

(52) U.S. Cl. 204/192.29; 204/192.26; 204/192.27; 204/192.28

(57) ABSTRACT

The invention disclosed is a process for fabrication of IR-transparent electrically conductive metal oxide, such as copper aluminum oxide (CuAlxOy), by reactive magnetron co-sputtering from high purity metal targets, such as Cu and Al targets, in an argon/oxygen g as mixture. A preferred embodiment of the present invention is a process for making a metal oxide film having electrical conductivity and infrared transparency. Preferably, the substrate is placed in an environment having argon and oxygen. The process comprises applying between about 0.15 to 10.0% oxygen partial pressure to a substrate and DC-sputter depositing a first layer of conductive metal ions onto the substrate. The first layer has a physical thickness of from about 13 to 20 angstroms. Next, Co-sputter depositing a second layer of infrared transparent delafossite metal oxide onto the first layer with the second layer having a physical thickness of from about 1500 to 5000 angstroms, thereby forming a layer pair. The Co-sputter depositing is accomplished with various combinations of RF-sputter depositing, pulsed-DC-sputter depositing, and DC-sputter depositing. The infrared transparency has a wavelength from about 0.7 microns to about 30 microns. In a more preferred embodiment, the process further comprises rotating the substrate during the DC sputter depositing and the Co-sputter depositing.

### CROSS REFERENCE TO RELATED APPLICATIONS

This application claims priority under 35 U.S.C. § 119(e) of U.S. provisional application No. 60/285,880 filed Apr. 20, 2001.

### STATEMENT REGARDING FEDERALLY SPONSORED RESEARCH OR DEVELOPMENT

The invention described herein may be manufactured and used by or for the government of the United States of America for governmental purposes without the payment of any royalties thereon or therefor.

### BACKGROUND OF THE INVENTION

1. Field of the Invention

This invention relates to the treatment of light transmissive surfaces including inorganic surfaces and organic polymer surfaces with antireflective coatings. More specifically, this invention relates to the fabrication of infrared (IR) transparent electrically conductive metal oxide films intended to shield light transmissive surfaces from electromagnetic interference (EMI) and reduce the radar cross section (RCS) of light transmissive surfaces. Additionally, this invention relates to the application of an antireflection coating on top of the IR transparent electrically conductive metal oxide film to reduce the Fresnel reflection losses from the conductive metal oxide film.

2. Description of the Prior Art

Military organizations are becoming increasingly concerned about high-power microwave (HPM) directed energy weapons (DEWS). These include everything from simple microwave devices that are easy to build and very effective to advanced concepts like the large aircraft HPM shield and the unmanned combat aerial vehicle (UCAV) HPM anti-electronics system. Windows and missile domes used to transmit visible and IR wavelengths need to be shielded with conductive coatings to prevent radio frequency and microwave electromagnetic radiation from entering and interfering with the electronic components inside the sensor system. In addition, retro-reflections from the internal components of an optical seeker or imaging system can result in a large RCS if the window or dome is not covered with an electrically conductive coating or grid. The technology being developed in this project will increase system survivability by shielding the internal electronics from EMI and by reducing the RCS of windows and missile domes. By using a continuous coating that has the required optical transparency and electrical conductivity, EMI shielding and reduced RCS can be achieved without degrading the off-axis performance of the seeker with unwanted scatter from a metal micromesh.

There are numerous commercial applications for erosion-resistant, optically transparent conductive coatings. The applications include aircraft windows, missile domes, scratch-resistant windshields, architectural shielding in industrial environments, view windows on magnetic resonance imaging (MRI) systems, windows in embassy buildings and other government installations, anti-fog periscope windows, and transparent electrodes for display devices such as liquid crystal displays (LCDs), light emitting diodes (LEDs), and flat panel displays. If the developed coatings could be applied onto polymeric substrates such as polycarbonate, a vast market would be opened that includes eyeglass lenses, instrument lenses, shatter-resistant windshields for automobiles, and impact-resistant anti-theft windows and doors. Other commercial applications for IR transparent, electrically conductive films include advanced infrared focal plane arrays (IRFPA) such as charge injection devices (CID), charge-coupled devices (CCD), and vertically integrated metal insulator semiconductor devices (VIMIS).

Metal mesh coatings on IR windows can be tailored to provide the required EMI shielding and IR transmittance by adjusting the shape, size, and spacing of the mesh openings and the thickness of the coating. However, metals are mechanically soft and easily damaged by rain and sand erosion. Durability of the metal mesh bond to the window under thermal cycling and thermal shock is also a major concern due to the large difference in the coefficients of thermal expansion (CTEs). If the coating can be made transparent to IR at the desired wavelengths, a continuous thin-film coating is preferable because it provides better erosion protection for the window and is easier to fabricate than its mesh counterpart. For a more detailed discussion, please refer to Johnson et al., “IR-Transparent Electrically Conductive CuAlₓO_{y} Deposited by ReactiveMagnetron Co-Sputtering”, Mat. Res. Soc. Symp. Session on Materials Science of Novel Oxide-Based Electronics, San Francisco Calif., Apr. 24-27, 2001, incorporated herein by reference.

Metallic micromeshes are soft and easily damaged and cannot be used on hypersonic-missile domes where thermal shock is a critical issue. For laser-spot trackers used in seeker systems like the Advanced Tactical Forward Looking Infrared (AT-FLIR), metallic grids can melt at the laser-power levels needed for adequate stand-off distances. Indium tin oxide (ITO) is a common transparent conductive oxide (TCO) that often is used on polycarbonate windscreens and aircraft canopies for static-charge dissipation and reduced RCS. Polycarbonate laminates and ITO coatings are easily scratched which limits the in-service life of canopies and windscreens on current aircraft like the Navy's F-18 and on advanced aircraft like the Joint Strike Fighter (JSF). A durable TCO coating would extend the in-service life, resulting in substantial cost savings for the F-18 and JSF transparency programs.

Commercially available TCOs like indium tin oxide (ITO) and zinc oxide most often are deposited by reactive-oxygen-sputter deposition. Unlike the p-type TCOs described in a preferred embodiment of the present invention, ITO and zinc oxide are n-type conductors and are not transparent at IR wavelengths longer than a bout 1 or 2 μm. In other words, ITO and zinc oxide coatings cannot be used on weapons systems that need to transmit the mid- and long-wave IR. In addition to being limited by their fundamental material properties to visible and near-IR applications, the production yield is low for ITO and zinc oxide films deposited using conventional sputter-deposition technology. A major reason for the low production yield is the formation of oxide layers on the metal targets when conventional rf power supplies are used. The formation of an oxide layer on a metal target eventually leads to serious arcing and sputter-rate control which results in defects and thickness non-uniformities in the deposited coatings. Fortunately, pulsed-dc-power supplies and arc-suppression controllers have become available in the past few years that provide much higher deposition rates and better control of reactive sputtering of insulator materials, especially aluminum oxide (Al₂O₃).

Recently, the first example of a TCO with p-type conductivity was demonstrated. Kawazoe, H. et al. “P-Type Electrical Conduction in Transparent Thin Films of CuAlO₂”, Nature, 389, 939-942, (1997). Kawazoe's group used laser ablation to deposit thin films of CuAlO₂ exhibiting p-type conduction. This is an exciting result because the higher effective-hole mass of the p-type carriers should push the plasma resonance further into the IR. A durable, p-type TCO like CuAlₓO_{y} with a tailorable bandgap and transparency in the IR could revolutionize the design and fabrication of photovoltaics and make solar energy a much more affordable alternative to fossil fuels. Kawazoe used x-ray diffraction (XRD) to show that p-type CuAlO₂ films deposited by laser ablation were polycrystalline and exhibited the crystalline structure of a novel class of metal oxides known as delafossites. Single crystals of delafossite metal oxides exhibit very anisotropic electrical properties. Specifically, the electrical conductivity is high in the direction perpendicular to the c-axis of the unit cell and is orders of magnitude lower in the direction parallel to the c-axis as described in Tanaka, M. et al. Physica B, 245, 157-163 (1998), which is incorporated herein by reference. The delafossite-CuAlO₂-unit cell is made up of layers of Cu⁺ cations, one atomic-dimension in thickness that are basically metallic. These layers of Cu⁺ are bound to layers of octahedrally coordinated Al³⁺ ions by O—Cu—O dumb-bells. The sheets of Cu⁺ metallic layers enhance electrical conductivity in the direction perpendicular to the c-axis while the oxygen atoms retard electrical conductivity in the direction parallel to the c-axis.

Cumulated Cu—O—Al—O—Cu bonds would require p_{z} orbitals on O to overlap with p_{z} orbitals on Al and d_{z}² orbitals on Cu atoms. Using a new technique that combines conventional XRD with electron-beam diffraction, it is possible to observe directly the classic textbook shape of a d_{z}² orbital in p-type Cu₂O as reported in Zuo J. et al. “Direct Observation of d-Orbital Holes and Cu—Cu Bonding in Cu₂O”, Nature, 401, 49-52 (1999), which is incorporated herein by reference. The work by Zuo el al., is expected to be a first step toward understanding high-temperature-superconducting-copper-oxide compounds.

U.S. Pat. No. 5,783,049 issued on Jul. 20, 1998 to Bright et al. discloses a method of making antireflective coating. However, the invention of the U.S. Pat. No. 5,783,049 patent concerns the use of n-type conductors. Unfortunately, they can't be used on weapons systems that need to transmit the mid- and long-wave IR wavelengths.

Sputter-depositing is a commercial process for depositing inorganic materials, metals, oxynitrides, oxides, and the like on surfaces. Representative descriptions of sputter-depositing processes and equipment may be found in U.S. Pat. No. 4,204,942 issued to Chadroudi on May 27, 1980 and U.S. Pat. No. 4,849,087 issued to Meyer on Jul. 18, 1989, which are incorporated by reference.

In sputtering, a voltage is applied to a metal or metal compound sputtering cathode in the presence of a reactive or non-reactive gas to create a plasma. The action of the sputtering gas plasma on the cathode causes atoms of the cathode (target) to be dislodged and to travel and deposit upon a substrate positioned adjacent to the sputtering source. Typically the sputtering gas is a noble gas such as krypton or argon or the like. Argon is the most common sputtering gas because of its attractive cost. It is also known in the art to employ from about 1 to about 90% (or even 100% in the case of a titanium target) of one or more reactive gases as components of a sputtering gas mixture. When a reactive gas is present, it causes a metal to be deposited as an oxide (when an oxygen source is present), an oxynitride (when an oxygen and nitrogen source is present) and the like. This reactive sputtering process is well known and used commercially.

### SUMMARY OF THE INVENTION

A preferred embodiment of the present invention is a process for making a metal oxide film having electrical conductivity and infrared transparency. The process comprises applying between about 0.15 to 10.0% oxygen partial pressure to a substrate and DC-sputter depositing a first layer of conductive metal ions onto the substrate. The first layer has a physical thickness of from about 13 to 20 angstroms. Next, Co-sputter depositing a second layer of infrared transparent delafossite metal oxide onto the first layer with the second layer having a physical thickness of from about 1500 to 5000 angstroms, thereby forming a layer pair. The Co-sputter depositing is accomplished with various combinations of RF-sputter depositing, pulsed-DC-sputter depositing, and DC-sputter depositing using one, two or three different metal or metal oxide targets. The infrared transparency has a wavelength from about 0.7 microns to about 30 microns. In a more preferred embodiment, the process further comprises rotating the substrate during the DC sputter depositing and the Co-sputter depositing.

In the process, the conductive metal ions are selected from the group consisting of Cu, Ag, Au, Pt and Pd. The delafossite metal oxide has the general formula ABₓO_{y}, as illustrated in FIG. 8. A is a monovalent metal (Me⁺¹) selected from the group consisting of Cu, Ag, Au, Pt, and Pd, B is a trivalent metal (Me⁺³) selected from the group consisting of Al, Ti, Cr, Co, Fe, Ni, Cs, Rh, Ga, Sn, In, Y, La, Pr, Nd, Sm, and Eu, x has a value from 0.25 to 4, and y has a value from 0.25 to 4. The DC-sputter depositing has a deposition rate between 0.1 Å per second and 1.0 Å per second and the Co-sputter depositing has a deposition rate between 0.5 Å per second and 5.0 Å per second.

One objective of a preferred embodiment of the present invention is to increase EMI/RFI shielding capacity of delafossite films by increasing their electrical conductivity and/or magnetic permeability.

Another objective of a preferred embodiment of the present invention is to provide a method of making a metal oxide film that will increase system survivability by shielding internal electronics from electromagnetic interference (EMI) and by reducing the RCS of windows and missile domes. By using a continuous coating that has the required optical transparency and electrical conductivity, EMI shielding and reduced RCS can be achieved without degrading the off-axis performance of the seeker with unwanted scatter from a metal micromesh.

Another objective of a preferred embodiment of the present invention is to provide a method of making a metal oxide film that may be used for laser-spot trackers used in seeker systems like the Advanced Tactical Forward Looking Infrared (AT-FLIR).

Another objective of a preferred embodiment of the present invention is to provide a method of making a metal oxide film that may replace the metal mesh used on a seeker window. A durable transparent conductive oxide (TCO) could replace the less scratch resistant, softer indium tin oxide (ITO). A durable TCO coating would extend the in-service life of canopies and widescreens, resulting in substantial cost savings.

Another objective of a preferred embodiment of the present invention is to provide a method of making a metal oxide film, which may control stoichiometry, crystallinity, and microstructure to increase electrical conductivity without loosing IR transmission of metal oxides based delafossites by doping the metal oxides with p-type dopants.

Another objective of a preferred embodiment of the present invention is to control the deposition conditions, crystallinity and orientation of deposited films.

Another object of a preferred embodiment of the present invention is to provide a method of making IR-transparent electrically conductive metal oxide by reactive magnetron co sputtering from metal targets in an argon-oxygen-gas mixture.

Another object of a preferred embodiment of the present invention is to provide a method of making IR-transparent electrically conductive metal oxide with improved control of deposition parameters like forward and reflected power and, consequently, much better control of film composition.

Another object of a preferred embodiment of the present invention is to provide a method of making IR-transparent electrically conductive metal oxide by applying the correct amount of power to each target and adjusting the oxygen-partial pressure to significantly reduced the growth of surface-oxide layers on the metal targets.

### BRIEF DESCRIPTION OF THE DRAWINGS

FIG. 1 is a graphical illustration of FTIR spectra for two CuAlₓO_{y} films. The trace a is for a 2990-Å-thick film that has a resistivity of 0.00076 ohm-cm and a sheet resistance of 26 ohm/sq. The trace b is for a 3800-Å-thick film that has a resistivity of 0.02 ohm-cm and sheet resistance of 540 ohm/sq.

FIG. 2 is a graphical illustration of FTIR spectra for films having underlying Cu layers of varying thickness. Deposition parameters for all three outer CuAlₓO_{y} layers are the same. Trace a is for a film with no underlying Cu layer; the 3140-Å-thick CuAlₓO_{y} has a resistivity of 51 ohm cm and sheet resistance of 1.6×10⁶ ohm/sq. Trace b is for a film with an underlying 13-Å-thick Cu layer; the 2640-Å-thick Cu/CuAlₓO_{y} has a resistivity of 0.040 ohm-cm and sheet resistance of 1470 ohm/sq. Trace c is for a film with an underlying 19-Å-thick Cu layer; the 2680-Å-thick Cu/CuAlₓO_{y} has a resistivity of 0.0055 ohm-cm and sheet resistance of 206 ohm/sq.

FIG. 3 is a graphical illustration of FTIR spectra for a CuAlₓO_{y} film before and after O₂ annealing. The trace a is for a 2893-Å-thick CuAlₓO_{y} film that had a resistivity of 0.0148 ohm-cm and a sheet resistance of 510 ohm/sq before annealing. The trace b is for the same film after annealing. The annealed film is very insulating.

FIG. 4 is a graphical illustration of FTIR spectra for two Cu/CuFexOy films. The trace a is for a 2822-Å-thick film that has a resistivity of 0.0056 ohm-cm and a sheet resistance of 197 ohm/sq. The trace b is for a 2296-Å-thick film that has a resistivity of 0.000381 ohm-cm and a sheet resistance of 16.6 ohm/sq.

FIG. 5 is a graphical illustration of high-resolution ESCA spectrum of a Cu/CuAlₓO_{y} film showing the deconvolved peaks for Cu 3 p¹ at 79.36 eV, Cu 3 p³ at 77.43 eV and Al 2 p at 74.76 eV.

FIG. 6 is a bright field image of a high resolution electron micrograph of a 500-Å-thick Cu/CuAlₓO_{y} film taken at a magnification of 150,000×.

FIG. 7 is a dark field image of a high resolution electron micrograph of a 500-Å-thick Cu/CuAlₓO_{y} film taken at a magnification of 150,000×.

FIG. 8 is an illustration of a desirable delafossite structure in a preferred embodiment of the present invention.

### DETAILED DESCRIPTION OF THE INVENTION

The present invention provides a method of making IR-transparent electrically conductive metal oxide films with p-type conductivity. An automated-research-coating (ARC) system equipped with three magnetron guns is used to deposit the metal oxide. For example, an ARC system equipped with three magnetron guns is used to deposit CuAlₓO_{y}, wherein x has a value between 0.25 and 4 and y has a value between 0.25 and 4, by co-sputtering from high-purity Al and Cu targets in a reactive Ar—O₂ mixture. In addition, the ARC system is used to deposit CuFeₓO_{y}, wherein x has a value between 0.25 and 4 and y has a value between 0.25 and 4, by co-sputtering from high-purity Fe and Cu targets and from a hot-pressed iron oxide target in a reactive Ar—O₂ mixture. Argon is the preferred inert gas, however, any inert gas may be used. The purity of each of the 2-inch-in-diameter Cu and Al metal targets is at least 0.99999. The 2 inch-in-diameter Fe target has a purity of 0.999. The 2-inch-in-diameter iron oxide target has an elemental purity of 0.999 and consists mostly of hematite (Fe₂O₃) powder with a small amount of magnetite (Fe₃O₄) powder. Each of the magnetron guns can be powered by any one of the following supplies which include one 6000W-asymmetric-bi-polar-pulsed-dc-power supply, two 5000W-asymmetric-bi-polar-pulsed-dc-power supplies, two 600W-rf-power supplies and one 250W-dc-power supply. The water-cooled chamber is a 12 inch in diameter by 14 inch high stainless-steel cylinder and is configured for downward sputtering onto a substrate with a target-substrate distance of about 5.5 inches. In a preferred embodiment of the present invention, the substrate underneath the guns is rotated. This results in good film uniformity over an 8 inch in diameter wafer. For CuAlₓO_{y} and CuFeₓO_{y}, the rotation speed of the substrate table may be set to about 10 rpm. The vacuum system consists of a 250 liter per second turbomolecular pump from VARIAN® and a direct drive oil-filled rough pump Trivac model D8B from LEYBOLD®. As the chamber is back-filled, the turbopump automatically slows down to half-speed to minimize the gas load and prevent excessive wear on the bearings. The O₂-partial pressure may range from about 0.1% to about 10%. Too much oxygen in the system may hinder the production of the desirable delafossite structure or the desirable electrically conductive structure. In a preferred embodiment, a combined Ar—O₂ gas flow rate of 27 sccm and a pump speed of 125 liters per second, the total pressure is maintained at about 14 millitorr. The chamber may be heated during pump-down using quartz lamps. With a thermocouple reading of 150° C., the base pressure of the chamber before starting the backfill may be less than 3×10⁻⁶ torr.

In a preferred embodiment of the present invention the substrate is constructed of a glass microscope slide partially covered by a mask for thickness measurement or a Silicon (Si) wafer for FTIR spectroscopy. However, various inorganic and polymer substrates are commercially available or can be prepared by various art-known processes. These substrates may be presented in any form, which yields a surface in need of a transparent conductive coating for EMI/RFI shielding and in need of antireflection. Such surfaces can be provided by solid bodies, by sheet films such as plastic sheet films ranging in thickness from about 0.2 mil to about 50 mils or by plastic films applied or laminated onto nonpolymeric surfaces such as glass.

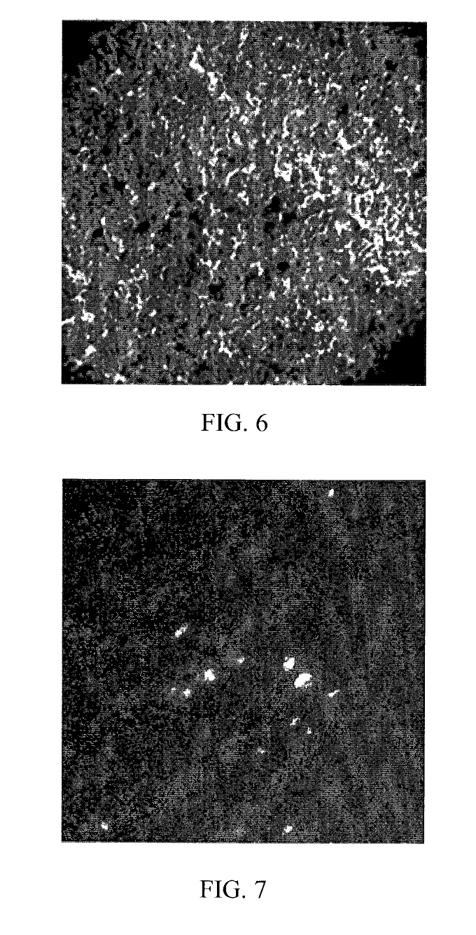

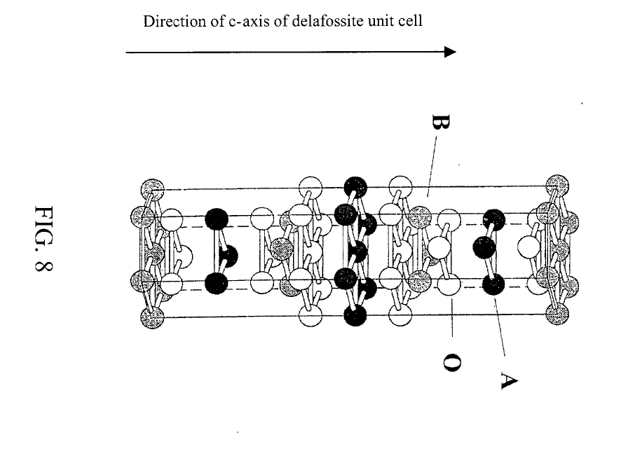

To allow for IR transmittance, the resistivity of the Silicon wafers was specified to be greater than 20 ohm-cm. Step heights were measured using a Tencor P-10 contact-stylus profiler. Room temperature resistivities of films deposited onto microscope slides were measured using a four-point probe, but the temperature range for these resistivity measurements may be from about 80° to about 520° Kelvin. Transmission spectra were measured using a Bio-Rad™ FTIR spectrophotometer. A single-beam spectrum of a coated-Silicon wafer is divided by a single-beam-background spectrum of an uncoated-Silicon wafer for all of the FTIR transmission spectra shown here. This approach is used to eliminate Silicon absorption bands from the spectra since only absorption from the coating is relevant in this invention. In addition, electron spectroscopy for chemical analysis (ESCA) was performed on a limited number of samples to determine the elemental compositions of the films. FTIR, ESCA and four-point-probe measurements were obtained with films that ranged in thickness from about 1500 to 5000 Å thick. A 500 Å thick film is deposited onto several 3 mm in diameter carbon grids for high resolution electron microscopy (HREM), illustrated in FIGS. 6 and 7, and electron energy loss spectroscopy (EELS). To provide an adequate amount of material for the inductively coupled plasma (ICP) emission measurement, a 4 inch in diameter Silicon wafer is coated with a 1.12-micron-thick film.

In a preferred embodiment of the present invention, dc power is incorporated for the Cu target and rf power is incorporated for the Al target. In a more preferred embodiment, pulsed-dc-power instead of rf power is incorporated for the Al target. In the most preferred embodiment, pulsed-dc-power is incorporated for the Cu target and pulsed-dc-power is incorporated for the Al target.

In a preferred embodiment of the present invention, dc power is incorporated for the Cu target, rf power is incorporated for the Fe target, and rf power is incorporated for the iron oxide target. In a more preferred embodiment, pulsed-dc power instead of dc power is incorporated for the Cu target.

The deposition rate for magnetic materials like Fe and iron oxide is very slow using conventional magnetron sputter cathodes because the magnetic target distorts the magnetic field lines of the cathode. With conventional magnetron designs, the magnetic target material absorbs the magnetic field lines of the center cathode magnet so that NO magnetic field lines extend above the target. The magnetic field lines must extend above the target for efficient sputtering to occur. To increase the sputter deposition rate from the Fe target, a thin foil of Mu-metal about 1-mm-thick was placed between the Fe target and the cathode block in the magnetron sputter gun. Mu-metal is sold by AD-Vanced Magnetics, Inc. (Rochester, Ind.) and is used in magnetic-field- and EMI/RFI-shielding applications. It is a Ni—Fe alloy that has a high magnetic permeability. The Mu-metal foil was inserted between the cathode block and the magnetic target to shield the target from the center cathode magnet. The intent was to cause the magnetic field from the outer ring magnets of the magnetron gun to extend above the target so some sputtering can occur. This approach successfully increased the sputter efficiency for the very magnetic Fe target and also for the slightly magnetic iron oxide target. By inserting the Mu-metal shielding foil behind the Fe and iron oxide targets, deposition rates of 1.3-Å-per-sec have been achieved for CuFeₓO_{y}. Without the Mu-metal foils, the deposition rates were only 0.6-Å-per-sec.

A magnetron cathode specifically designed for sputter depositing magnetic materials is available from AJA International. In the AJA International design, the center magnet is replaced with an iron plug that is plated with chrome to prevent oxidation since the plug is water-cooled. The iron plug optimizes saturation of the magnetic target thereby allowing some field lines to extend above the target surface. The close magnet proximity allows reasonably thick magnetic targets (3-mm-thick Fe and 6-mm-thick Ni) to be used.

Asymmetric bi-polar pulsed-dc-power supplies for reactive-sputter deposition became commercially available in the 1990s. If applied properly, pulsed-dc-power technology can minimize the arcing problems encountered when reactively sputtering oxide compounds like Al₂O₃ from high-purity-metal targets. With the asymmetric bi-polar pulsed-dc-power supplies manufactured by Advanced Energy Industries, Inc. (Fort Collins, Colo.), the duration and magnitude of the reverse bi-polar pulse can be adjusted to discharge and etch away the unwanted oxide layer that forms on the metal target during reactive-oxygen-sputter deposition. Continuous discharging and etching of the oxide layer from the metal target allows much better control of the sputter rate and eliminates the large “hard” arcs and the micro-arcs that produce undesirable thin-film microstructure and composition defects. Dense, low-defect Al₂O₃ films have been deposited with the 5 KW Pinnacle Plus pulsed-dc-power supply from Advanced Energy Industries, Inc. using a pulse rate of 50 kHz with the magnitude of the reverse pulse set at 20% of the target bias voltage and the duration of the reverse pulse set at 5 μsec. With a conventional rf-power supply operating at a set frequency of 13.56 MHz, the forward-sputter and reverse-etch portions of the waveform have the same magnitude and duration; there is no way to adjust the duration or magnitude of the reverse etch portion to gradually clean away and discharge the oxide layer on the target. The oxide layer continues to form and the sputter-deposition rate continues to drop until the charge on the oxide layer gets high enough to cause severe dielectric breakdown. This produces a hard uncontrolled arc that dislodges non-uniform pieces of material from the target resulting in growth defects and composition variations in the deposited film. Since small composition changes can cause large differences in the optical and electrical properties of a TCO, elimination of uncontrolled arcing is very desirable. Fabricating high-quality TCOs using conventional rf-power supplies is difficult and expensive. The newer pulsed-dc power supplies can significantly reduce the cost of producing the high-quality TCOs needed for a variety of commercial products.

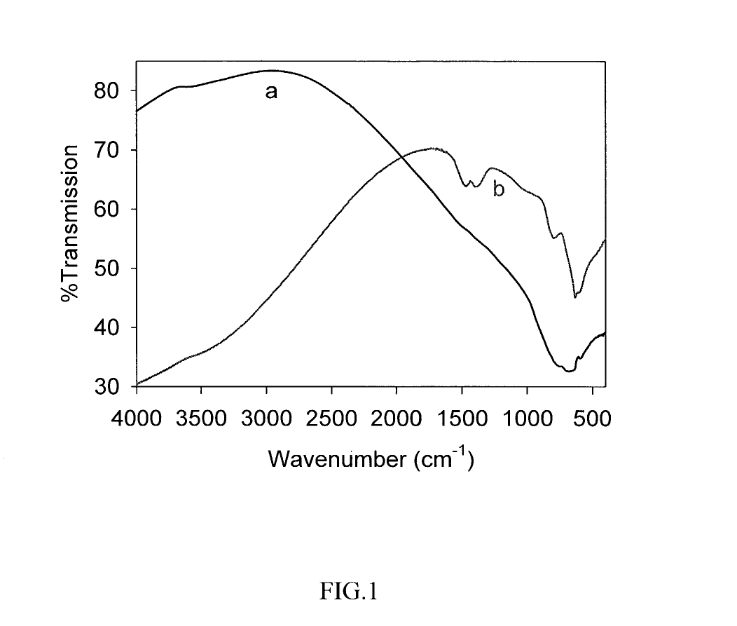

The trace a in FIG. 1 shows the transmission spectrum of a 2990-Å-thick CuAlₓO_{y} film that has a resistivity of 0.00076 ohm-cm and a sheet resistance of 26 ohm/sq. Deposition parameters were 20W dc power applied to the Cu target, 200W rf power applied to the Al target, and 3% O₂ partial pressure. In a preferred embodiment of the present invention, the deposition rate is between about 0.5 and 5 Å per second. In a more preferred embodiment of the present invention, the deposition rate is about 3 Å per second. Prior to turning on the O₂ partial pressure and before starting the deposition of the CuAlₓO_{y} film, approximately 19 Å of Cu metal is deposited using 100% Ar and a second high-purity-Cu target. The trace b in FIG. 1 is an FTIR spectrum of one of the first CuAlₓO_{y} films deposited using a prior art method and illustrates the benefit of the method of the present invention. Since the initial demonstration of p-type IR transparent metal oxide coatings by magnetron-sputter deposition in the prior art, p-type IR transparent metal oxide films of the present invention reduce the resistivity of the metal oxide coating by more than a factor of 4 from 0.020 to 0.0048 ohm-cm. In addition, transmission in the mid-wave IR has increased from 70% to almost 90%.

The role of the thin underlying Cu layer is not fully understood. However, the following paragraphs describe experimental evidence that shows the thin Cu layer is needed to promote the growth of the appropriate microstructure for enhanced electrical conductivity and IR transparency in the overlying CuAlₓO_{y} and CuFeₓO_{y} films.

By itself, the Cu is too thin to contribute significantly to the conductivity. This was verified when four-point-probe measurements were made on a glass slide half-coated with a 19-Å-thick-Cu layer. The 19-Å-thick Cu-coated half was found to be as electrically insulating as the uncoated half of the glass slide.

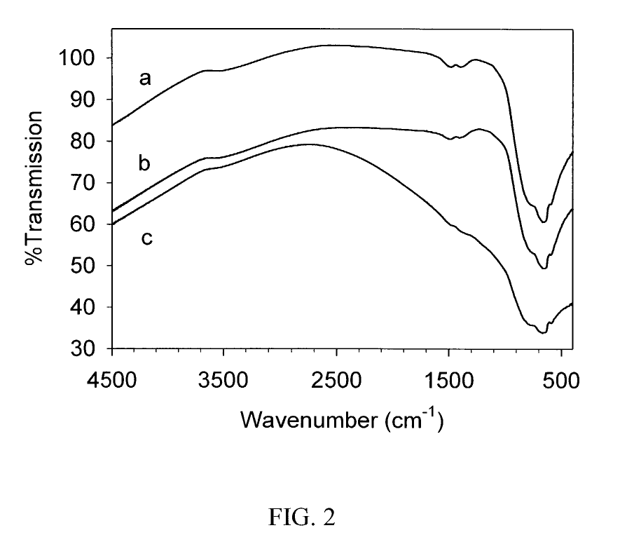

FIG. 2 summarizes the effect of depositing thin Cu layers of varying thickness at the beginning of the CuAlₓO_{y} coating run. Deposition conditions for the outer layer of CuAlₓO_{y} were the same for all three films: 170W dc power applied to the Cu target, 280W rf power applied to the Al target, 1.1% O₂ partial pressure and a 15 minute long deposition time. For the film in trace a, no thin layer of Cu was deposited at the beginning of the coating run. The resulting 3140 Å thick CuAlₓO_{y} film was very transparent but was only semi-conductive with a resistivity of 51 ohm-cm and a sheet resistance of 1.6×10⁶ ohm/sq. For the film in trace b, approximately 13 Å of Cu was deposited first followed by the outer layer of CuAlₓO_{y}. The resulting 2640 Å thick Cu/CuAlₓO_{y} film was more than 80% transparent from 3125 to 1042 cm⁻¹ and was conductive with a resistivity of 0.040 ohm-cm and a sheet resistance of 1470 ohm/sq. For the film in trace c, approximately 19 Å of Cu metal was deposited first followed by the outer CuAlₓO_{y}. The resulting 2680-Å-thick Cu/CuAlₓO_{y} film was more than 70% transparent from 4000 to 1961 cm⁻¹ and was very conductive with a resistivity of 0.0055 ohm-cm and a sheet resistance of 206 ohm/sq. Notice that the thickness values for the films deposited onto Cu were about 85% of the thickness value for the film deposited directly onto the substrate even though the deposition conditions and deposition times were identical for all three CuAlₓO_{y} layers. In other words, the more conductive films have microstructures that are more compact than those of the less conductive films. This is similar to what occurs in high-temperature-copper-oxide superconductors where the microstructure of the superconducting phase is more compact than the microstructure of the non-superconducting phase.

Experiments were done to determine if replacing the thin Cu layer with a thin layer of Al or tin (Sn) would also promote the growth of a CuAlₓO_{y} film that has enhanced conductivity and IR transparency. Replacing the thin Cu layer with a thin layer of Al resulted in CuAlₓO_{y} films that were significantly more transparent in the IR but were also more than three orders of magnitude less conductive. In other words, a thin Al layer does not promote the growth of a film that has enhanced electrical conductivity and IR transparency; the CuAlₓO_{y} film that grows on top of the thin Al layer has properties very similar to a CuAlₓO_{y} film that is grown on a bare substrate. A thin Sn layer also does not promote the growth of a CuAlₓO_{y} film that has enhanced electrical conductivity and IR transparency.

The role of the underlying copper layer in the TCOs fabricated in this invention is very different from the role of the metal layers in the photonic bandgap concepts fabricated by Scalora, et al [J. Appl. Phys., 83(5) pp. 2377-2383 (1998)]. First of all, photonic bandgap concepts cannot be used for applications requiring electrical conductivity and transparency at IR frequencies less than 10,000 cm⁻¹. (A frequency of 10,000 cm⁻¹ is the same as a wavelength of 1 micron.) When the metal layers in the photonic bandgap designs are thick enough to provide the required electrical conductivity, they have too much absorption to allow for adequate transparency at frequencies less than 10,000 cm^{31 1}. Furthermore, to avoid degrading the electrical conductivity of the metal layers in the photonic bandgap designs, the metal layers must NOT be oxidized during deposition of the dielectric layers. For photonic bandgap concepts that employ metal layers that are easily oxidized such as silver (Ag), Al and Cu, the choice for the dielectric layer is limited to materials such as magnesium fluoride (MgF₂) that have low values of refractive index and also will NOT oxidize the metal layer during the deposition process, thereby, degrading its electrical conductivity. There are many oxides such as silicon dioxide (SiO₂), tantalum oxide (Ta₂O₃) and Al₂O₃ that have low values of refractive index but are NOT chosen as the dielectric layers in the photonic bandgap designs because oxygen is either evolved during the deposition process or must be added to the vacuum chamber to maintain the correct stoichiometry for the required optical properties of the oxides. M. Bloemer and M. Scalora deposited layers of MgF₂ onto the Ag layers in their photonic bandgap concepts instead of depositing layers of a low-refractive-index oxide such as SiO₂ onto the Ag layers [M. Bloemer and M. Scalora, Appl. Phys. Lett. 72 (14) pp. 1676-1678 (1998)]. The oxygen needed to maintain the stoichiometry of the SiO₂ would have oxidized the Ag resulting in degraded values of electrical conductivity.

Unlike the photonic bandgap designs, an oxide layer of electrically conductive, IR-transparent CuAlₓO_{y} or CuFeₓO_{y} is deposited on top of the thin layer of easily-oxidized Cu in the invention described here. The underlying Cu layer is very susceptible to oxidation during deposition of the overlying CuAlₓO_{y} or CuFeₓO_{y} layer. However, oxidation of the Cu layer does not degrade the electrical conductivity of the overlying CuAlₓO_{y} or CuFeₓO_{y} layer. The electrical conductivity does NOT come from the underlying metal layer; it is a result of the electrical conductivity of the CuAlₓO_{y} or CuFeₓO_{y} layer. Clearly, the role of the thin copper layer in this invention is very different from that of the metal layers in the photonic bandgaps designed and fabricated by M. Bloemer and M. Scalora.

The thin underlying copper layer in this invention appears to promote the growth of the appropriate microstructure needed for enhanced electrical conductivity and IR transparency in the overlying CuAlₓO_{y} and CuFeₓO_{y} films. If the thin layer of Cu is omitted, the films are less conducting. Furthermore, as the thickness of the overlying CuAlₓO_{y} or CuFeₓO_{y} film increases, the ability of the underlying Cu layer to maintain the appropriate microstructure decreases.

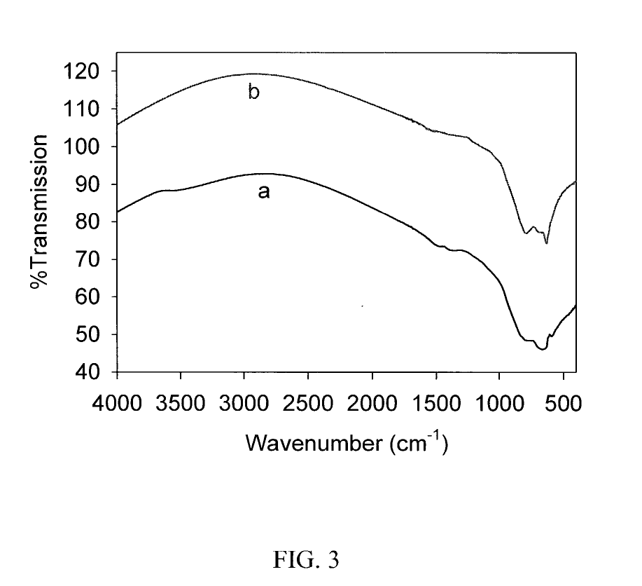

The trace a in FIG. 3 is an FTIR spectrum of a 2893 Å thick CuAlₓO_{y} film with a resistivity of 0.0148 ohm-cm and a sheet resistance of 510 ohm/sq. The gray trace is an FTIR spectrum of the same film after it is annealed in a high-vacuum chamber at 600° C. in O₂ for five hours. The peak transmission before annealing is 92.9% and after annealing is 119.3%. The annealed film is very electrically insulating with a sheet resistance of greater than 1×10⁹ ohm/sq. Another difference between the as-deposited and annealed film is the absence of the pair of small absorption bands at 1470 and 1395 cm⁻¹ in the spectrum of the annealed film. The pair of weakly intense bands at 1470 and 1395 cm^{31 1} is present in spectra of films that exhibit enhanced % electrical conductivity. When these bands are absent, the CuAlₓO_{y} films have high values of resistivity. It is possible that the enhanced conductivity of sputter-deposited CuAlₓO_{y} films could be a result of overlapping d orbitals on neighboring Cu¹⁺ atoms in the plane perpendicular to the c-axis of the delafossite-unit cell. Overlapping d orbitals also would explain why the sputter-deposited CuAlₓO_{y} films absorb strongly in the visible. Another possibility is that the 1470 and 1395 cm⁻¹ bands involve vibrational modes of the entire Cu—O—Al—O—Cu sequence along the c-axis of the delafossite-unit cell.

Cuprous oxide (Cu₂O) absorbs strongly at 609 cm⁻¹. Randomly oriented Al₂O₃ has a strong absorption centered at about 670 cm⁻¹ with shoulders at 560 and 750 cm⁻¹. The fact that the frequencies of the 1470 and 1395 cm⁻¹ bands are about twice those of the major lattice vibrations in Cu₂O and Al₂O₃ is significant and indicates that these modes may involve cumulated Cu—O═Al—O═Cu double bonds. Higher-order π bonding would tend to enhance carrier mobility. Higher-order bonding in a metal oxide also would result from an oxygen vacancy.

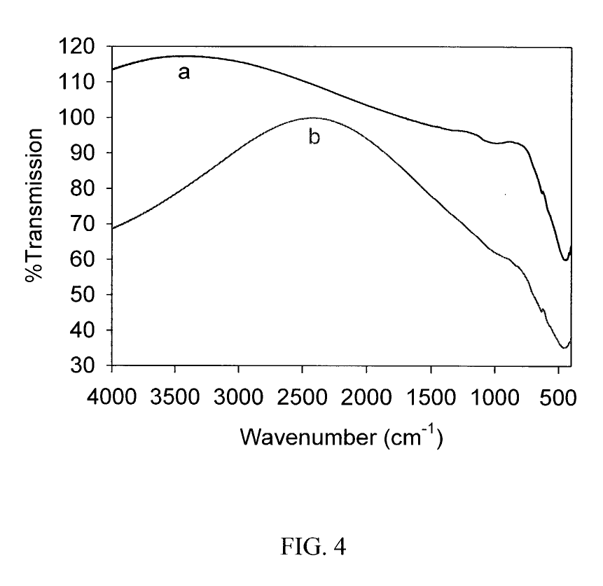

FIG. 4 is a graphical illustration of FTIR spectra for two Cu/CuFeₓO_{y} films. The trace a in FIG. 4 is for a 2822-Å-thick Cu/CuFeₓO_{y} film that has a resistivity of 0.0056 ohm-cm and a sheet resistance of 197 ohm/sq. Deposition parameters were 46W dc power applied to the Cu target, 185W rf power applied to the iron oxide target, and 0.6% O₂ partial pressure. The trace b is for a 2296-Å-thick Cu/CuFeₓO_{y} film that has a resistivity of 0.000381 ohm-cm and a sheet resistance of 16.6 ohm/sq. Deposition parameters were 50W dc power applied to the Cu target, 180W rf power applied to the iron oxide target, 300W pulsed dc power applied to the Fe target and 0.3% O₂ partial pressure. For both of the films, approximately 19 Å of Cu metal was deposited prior to turning on the O₂ partial pressure and before starting the deposition of the overlying CuFeₓO_{y}.

A pair of weak FTIR absorption bands at about 1080 and 990 cm⁻¹ can be seen most clearly in trace a of FIG. 4. Just as weak FTIR absorption bands at about 1485 and 1390 cm⁻¹ are associated with enhanced electrical conductivity and IR transparency in the CuAlₓO_{y} films, so are the 1080 and 990 cm⁻¹ bands in the CuFeₓO_{y} films. It is important to note that the frequencies of these doublets scale inversely with the square root of the atomic masses of Fe and Al. This is further evidence that the bands involve cumulated double bonds along the c-axis of the delafossite compounds.

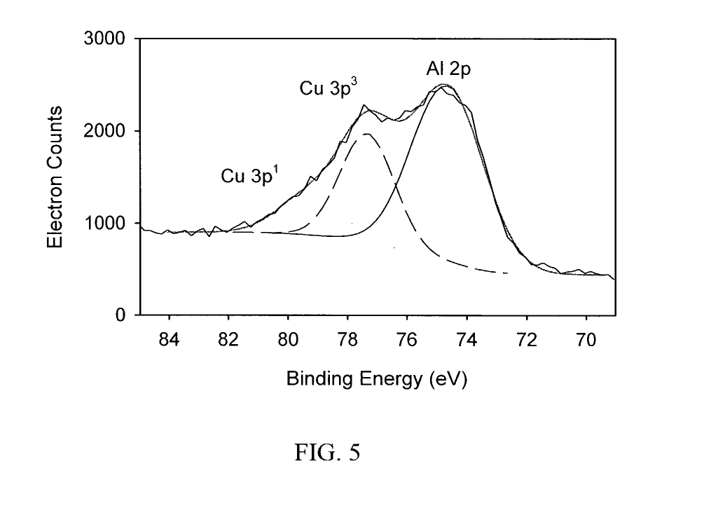

FIG. 5 is a high-resolution-ESCA spectrum for one of the most electrically conductive and IR transparent CuAlₓO_{y} films. The spectrum has been deconvolved into three distinct peaks with the Cu 3 p⁻¹ peak at 79.36 eV contributing about 12%, the Cu 3 p³ peak at 77.43 eV contributing about 28.5% and the Al 2 p pea k at 74.76 eV contributing about 59.5%.

Although ESCA is only semi-quantitative, the high-resolution ESCA spectrum clearly shows that the film is Al rich. The more quantitative method of inductively coupled plasma (ICP) emission spectroscopy shows the Al:Cu ratio in the CuAlₓO_{y} film is about 2:1. Even with a very non-stoichiometric composition, the CuAlₓO_{y} film is very conductive with a resistivity of 0.0051 ohm-cm, a sheet resistance of 246 ohm/sq, and a peak IR transmission of 67%. Like the black trace in FIG. 1, the FTIR spectrum of this film (not shown here) has a broad absorption from about 2500 to 800 cm⁻¹ resembling the broad phonon absorption in Al₂O₃ films. This broad absorption along with resistivity measurements indicates that most of the extra Al goes into the CuAlₓO_{y} films as oxide rather than free metal. The excess Al—O bonds make the CuAlₓO_{y} films extremely hard and scratch resistant. However, too many Al—O bonds eventually degrade the electrical conductivity.

Atomic force microscopy (AFM) and high-resolution electron microscopy (HREM) indicate that magnetron-sputter-deposited CuAlₓO_{y} is not a single-phase material. A second Cu-rich phase appears to be contributing to the enhanced electrical conductivity. Although not shown here, the phases and grain sizes in the AFM images are similar to those in the HREM images shown in FIGS. 6 and 7. The HREM images indicate that the 500-Å-thick CuAlₓO_{y} film consists of islands of crystalline elemental-Cu particles in an amorphous Cu—Al—O matrix. The size of the Cu particles is about 40 to 50 nm. Electron energy loss spectroscopy (EELS) was used to show that the dark spots in the bright field image in FIG. 6 are cubic-Cu crystallites and that the Cu—Al—O matrix has a ratio of Al:Cu of 1:1 with O attached to both Al and Cu. FIG. 7 is simply a dark field image of the same area shown in FIG. 6 where the light spots are now the cubic-Cu crystallites. It is likely that the elemental-Cu particles are partly a result of diffusion of the thin layer of Cu that was deposited onto the substrate and then overcoated with about 480 Å of CuAlₓO_{y}. At first, the Al:Cu ratio determined by EELs appears to contradict the ICP and ESCA data that show the Al:Cu ratio is 2:1. This apparent contradiction is probably related to the fact that the overlying CuAlₓO_{y} layers in the ICP and ECSA samples were much thicker. The CuAlₓO_{y} layers had to be thinner to allow for transmission of electrons through the HREM samples. As the thickness of the CuAlₓO_{y} layer increases, the ability of the thin underlying layer of Cu to promote the growth of the correct microstructure and composition for enhanced transparency and conductivity probably diminishes. It may be necessary to periodically increase and then decrease the concentration of elemental Cu during the deposition of the overlying CuAlₓO_{y} layer to maintain the optimum composition and microstructure. Preliminary attempts to do this indicate that the amount of elemental Cu needed is very small.

The substrate also has a dramatic effect on the properties of the resulting CuAlₓO_{y} or CuFeₓO_{y} film probably by influencing the nucleation and formation of islands of cubic —Cu metal during the deposition of the thin underlying Cu layer. If the underlying Cu layer is too thin, the film deposited onto the glass microscope slide often has much higher sheet resistance than one deposited onto the single-crystal-Si wafer. For example, a CuAlₓO_{y} film has a sheet resistance of is 26 ohm/sq when deposited onto single-crystal Si while the same film from the exact same coating run has a sheet resistance of 132 ohm/sq when deposited onto a glass microscope slide. For films from the same coating run, the films deposited onto single-crystal Si consistently have lower sheet resistance than those deposited onto glass microscope slides. Th e nucleation and formation of islands of cubic-copper metal is probably more uniform on the single-crystal-Si wafers because they have much better surface finishes, higher purity and fewer defects than the glass microscope slides.

For CuFeₓO_{y} films from the same coating run, the sheet resistance is 367 ohm/sq on fused silica, 258 ohm/sq on single-crystal Si and only 98 ohm/sq on single-crystal sapphire. These results show that it is much easier to achieve good IR transparency and good electrical conductivity for films deposited onto c-axis-single-crystal sapphire than for films deposited onto other substrates. In addition to being crystalline, measured values of surface roughness for the Si and sapphire substrates are much lower than those for the glass microscope slides and fused silica substrates.

Additional insight into the role of the underlying Cu layer was obtained when it was shown that the resistivity of a CuAlOₓ. film could be lowered by approximately a factor of 40 with an external electrical bias. A Si wafer coated with a 4200-Å-thick-CuAlOₓ film was placed on a thin strip of copper-sheet metal. The strip of copper was used as the bottom electrode and a copper-voltage probe was used as the top electrode. A four-point probe with the probe current set to 5 microAmps was used to measure the film's resistivity under three different bias conditions. With no bias applied, the measured resistivity was 0.013 ohm-cm and the sheet resistance was 310 ohm/sq. With a positive bias voltage of up to 4V applied to the top electrode, the measured resistivity remained constant at 0.013 ohm-cm. When a negative bias voltage of up to 1.2V was applied to the top electrode, the measured resistivity gradually dropped by approximately a factor of 40 to a minimum of 0.0003 ohm-cm. In other words, the external electrical bias brought the resistivity down to 7 ohm/sq from a value of 310 ohm/sq in the unbiased state. Higher negative voltages bring the resistivity back to the unbiased state. It is possible that the external bias is allowing the 20-Å-thick-Cu layer underneath the 4200-Å-thick-CuAlOₓ, film to act as a hole-injecting anode which allows charge carriers to be injected into the active metal oxide layer. This is similar to the large-workfunction, hole-injecting anode contacts that are used in almost all of the organic light-emitting diodes that are fabricated today [H. Klauk, et al, Thin Solid Films 366 (2000) 272-278].

In a preferred embodiment, application of pulsed dc power to all three targets allows much better control of the deposition process and the resulting film composition. Without tight control of process parameters and composition, it was difficult to understand the trade-off between IR transmission and electrical conductivity. Transmission loss is a function of the real and imaginary parts of the refractive index. With better process control, it now is easier to see that as the optimum composition for high electrical conductivity and low IR extinction coefficient k is approached, there is a rapid increase in the real part n of the refractive index. For example, a 4200-Å-thick film with n=2.42 and transmission of 101% at a wavelength of 4.05 microns (compared to an uncoated Si wafer) has a resistivity of 0.013 ohm-cm while a 3900-Å-thick film with a value of n=3.97 and transmission of 53% at a wavelength of 6.24 microns (compared to an uncoated Si wafer) has a resistivity of 0.0034 ohm-cm. For the most conductive films, values of n can be as high as 4.7. The large Fresnel reflection losses of the more conductive metal oxide films are easily compensated for with an antireflection coating.

An excellent three-layer antireflection coating for the near- and mid-wave IR involves a layer of silicon hydride (SiH) deposited onto the conductive metal oxide, followed by an intermediate layer of silicon nitride (Si₃N₄) and finished with an outer layer of silicon dioxide (SiO₂). By adjusting the partial pressure of hydrogen during reactive-sputter deposition from a high-purity silicon target, it is possible to tailor the refractive index of SiH from a high value of about 3.2 to a low value of about 2.8. In the near and mid-wave IR, the refractive index of Si₃N₄ has a value of about 1.95 and the refractive index of SiO₂ has a value of about 1.42. Depositing the SiH and Si₃N₄ layers first protects the metal oxide from oxidation during the deposition of the SiO₂ layer. If the SiO₂ layer were deposited directly onto the metal oxide layer, the conductivity would be degraded.

The Pinnacle Plus 5 kW Model from Advanced Energy Industries, Inc. is an asymmetric bipolar pulsed dc magnetron power supply that allows control of the pulsing frequency over the entire range from 5 to 350 kHz. Frequency control is important since different insulator materials are sputtered most effectively at different pulsed-dc frequencies. For example, the optimum pulsing frequency for Al₂O₃ is about 50 kHz while that for copper oxide (CuO₂) is only 5 kHz. The Pinnacle Plus also provides control over the duration and magnitude of the reverse voltage bias. The oxide layer is preferentially sputtered from the metal target during the reverse voltage pulse so having control of the magnitude and duration is important since different oxide materials will be etched at different bias thresholds and at different rates. The Pinnacle Plus also comes with an arc suppressor that provides microsecond-arc detection and quenching. Arcing robs the plasma of energy so the arc-suppression capability enhances plasma energy and density.

In a preferred embodiment of the present invention, the sputter deposited films are amorphous and exhibit isotropic electrical conductivity. By making the film oxygen deficient, it is possible to enhance the electrical conductivity without degrading the IR transparency significantly. FTIR spectra presented here will show that a pair of weakly intense absorption bands at 1470 and 1395 cm⁻¹ is present in CuAlₓO_{y} films that have enhanced electrical conductivity and IR transparency. The fact that the frequencies of the 1470 and 1395 cm⁻¹ bands are about twice those of the major phonons in Cu₂O and Al₂O₃ is significant and indicates that this pair of bands may involve cumulated Cu—O—Al—O—Cu double bonds along the c-axis, as illustrated in FIG. 8. The delafossite metal oxides as illustrated in FIG. 8 have the general chemical formula ABₓO_{y} where A is a monovalent metal (Me⁺¹) such as Cu, Ag, Au, Pt, or Pd while B is a trivalent metal (Me³⁺) such as Al, Ti, Cr, Co, Fe, Ni, Cs, Rh, Ga, Sn, In, Y, La, Pr, Nd, Sm, or Eu. In FIG. 8, x has a value of 1 and y has a value of 2. However, with respect to the general formula of ABₓO_{y}, x has a value of 0.25 to 4 and y has a value of 0.25 to 4. As indicated by the arrow, the c-axis of the delafossite unit cell is parallel to the long axis of the diagram. Higher-order bonding tends to enhance carrier mobility. Furthermore, higher-order bonding in a metal oxide would likely result from an oxygen deficiency. Understanding the origin of these bands could speed development of magnetron-sputter-deposited CuAlₓO_{y} as a wide-bandgap-conductive oxide since these bands are clearly associated with enhanced conductivity and carrier mobility. The delafossite structure of CuAlO₂ to some degree mimics the structures of high-temperature-superconducting-copper-oxide compounds on an atomic scale. The pair of bands at 1470 and 1395 cm⁻¹ may be associated with the phonon-assisted electrical conduct ion and Cooper-pair phenomena that are used to explain superconductivity. Hall-effect measurements also show that our CuAlₓO_{y} films are p-type so lattice vibrations probably are involved in the enhanced conductivity.

When sputtering with a partial pressure of oxygen, the sputter rate from the trivalent metal (Me⁺³ such as Al, Fe, etc.) target is much lower than that from the monovalent metal (Me⁺¹ such as Cu, Au, Pd, Pt) target. This is mainly because the oxide layer that forms on the trivalent metal target is much harder mechanically than the oxide layer that forms on the monovalent metal target. To achieve comparable deposition rates for the trivalent and monovalent metals, a preferred embodiment uses one monovalent metal target running at the lowest power possible and two trivalent metal targets running at the highest powers possible. There is a minimum power of about 20W below which the plasma will not stay lit. Also, there is a maximum power that the guns and targets can tolerate. To avoid excessive heating, the maximum RF power that can be applied to a 2-inch-diameter target is about 200W. At higher powers, there also is excessive oxide formation on the target and arcing. Although heating is not a major problem for DC operation, the maximum DC or pulsed DC power that can be applied to a two-inch-diameter target is about 300W. At higher DC and pulsed DC powers, there is excessive oxide formation on the targets.

For the CuFeₓO_{y} films, the sputter rate from the iron (Fe) target was extremely low because the target is magnetic. To increase the deposition rate for the Fe, we used an iron oxide target in addition to an iron target. The iron oxide target was less magnetic than the iron target and the deposition rate was higher.

Cumulated Cu—O—Al—O—Cu bonds would require p_{z} orbitals on O to overlap with p_{z} orbitals on Al and d_{z}² orbitals on Cu atoms. Using a new technique that combines conventional is XRD with electron-beam diffraction, Zuo et al. were able to observe directly the classic textbook shape of a d_{z}² orbital in p-type Cu₂O. The work by Zuo et al. is expected to be a first step toward understanding high-temperature-superconducting-copper-oxide compounds and may help explain the enhanced conductivity and IR transparency in the sputter-deposited CuAlₓO_{y} films of the present invention.

Although the description above contains many specificities, these should not be construed as limiting the scope of the invention but as merely providing an illustration of the presently preferred embodiment of the invention. Thus the scope of this invention should be determined by the appended claims and their legal equivalents.

What is claimed is:

1. A process for making a metal oxide film having electrical conductivity and infrared transparency, comprising:
applying between about 0.15% to 10.0% oxygen partial pressure to a substrate;
DC-sputter depositing onto said substrate a first layer of conductive metal ions having a physical thickness of from about 13 to 20 angstroms; and
Co-sputter depositing from at least one target onto said first layer a second layer of infrared transparent delafossite metal oxide having a physical thickness of from about 1500 to 5000 angstroms, thereby forming a layer pair.

2. The process of claim 1, said Co-sputter depositing selected from the group consisting of RF-sputter depositing, pulsed-DC-sputter depositing, DC-sputter depositing and any combination thereof.

3. The process of claim 1, said infrared transparency comprising a wavelength from about 0.7 microns to about 30 microns.

4. The process of claim 1 further comprising:
rotating said substrate during said DC sputter depositing; and
rotating said substrate during said Co-sputter depositing.

5. The process of claim 1, wherein said conductive metal ions are selected from the group consisting of Cu, Ag, Au, Pt and Pd.

6. The process of claim 1, said delafossite metal oxide having the formula ABₓO_{y},
wherein A is a monovalent metal having a metal source selected from the group consisting of Cu, Ag, Au, Pt, and Pd,
wherein B is a trivalent metal having a metal source selected from the group consisting of Al, Ti, Cr, Co, Fe, Ni, Cs, Rh, Ga, Sn, In, Y, La, Pr, Nd, Sm, and Eu,
wherein x has a value from 0.25 to 4, and
wherein y has a value from 0.25 to 4.

7. The process of claim 1, said DC-sputter depositing having a deposition rate between 0.1 Å per second and 1.0 Å per second.

8. The process of claim 1, said Co-sputter depositing having a deposition rate between 0.5 Å per second and 5.0 Å per second.

9. The process of claim 1, said Co-sputter depositing

10. A process for making a metal oxide film having a delafossite structure, comprising:
placing a substrate in an atmosphere comprising argon and between about 0.15% to 10.0% oxygen partial pressure;
DC-sputter depositing onto said substrate a first layer of conductive metal ions having a physical thickness of from about 13 to 20 angstroms; and
Co-sputter depositing from at least one target onto said first layer a second layer of infrared transparent delafossite metal oxide having a physical thickness of from about 1500 to 5000 angstroms, thereby forming a layer pair.

11. The process of claim 10, said Co-sputter depositing selected from the group consisting of RF-sputter depositing, pulsed-DC-sputter depositing, DC-sputter depositing and any combination thereof.

12. The process of claim 10, said infrared transparency comprising a wavelength from about 0.7 microns to about 30 microns.

13. The process of claim 10 further comprising:
rotating said substrate during said DC sputter depositing; and
rotating said substrate during said Co-sputter depositing.

14. The process of claim 10, wherein said conductive metal ions are selected from the group consisting of Cu, Ag, Au, Pt and Pd.

15. The process of claim 10, said delafossite metal oxide having the formula ABₓO_{y}
wherein A is a monovalent metal having a metal source selected from the group consisting of Cu, Ag, Au, Pt, and Pd,
wherein B is a trivalent metal having a metal source selected from the group consisting of Al, Ti, Cr, Co, Fe, Ni, Cs, Rh, Ga, Sn, In, Y, La, Pr, Nd, Sm, and Eu,
wherein x has a value from 0.25 to 4, and
wherein y has a value from 0.25 to 4.

16. The process of claim 10, said DC-sputter depositing having a deposition rate between 0.1 Å per second and 1.0 Å per second.

17. The process of claim 10, said Co-sputter depositing having a deposition rate between 0.5 Å per second and 5.0 Å per second.

18. The process of claim 6, said at least one target comprising three targets, wherein said three targets comprises:
one of said monovalent metals; and
two of said trivalent metals.

19. The process of claim 15, said at least one target comprising three targets, wherein said three targets comprises:
one of said monovalent metals; and
two of said trivalent metals.

20. A process for making a metal oxide film having a delafossite structure, comprising:
placing a substrate in an evacuated chamber having an atmosphere comprising argon and oxygen;
applying between about 0.15% to 10.0% oxygen partial pressure to said substrate;
DC-sputter depositing onto said substrate a first layer of conductive metal ions having a physical thickness of from about 13 to 20 angstroms; and
Co-sputter depositing from at least one target onto said first layer a second layer of infrared transparent delafossite metal oxide having a physical thickness of from about 1500 to 5000 angstroms, thereby forming a layer pair.

21. The process of claim 20, said Co-sputter depositing selected from the group consisting of RF-sputter depositing, pulsed-DC-sputter depositing, DC-sputter depositing and any combination thereof.

22. The process of claim 20, said infrared transparency comprising a wavelength from about 0.7 microns to about 30 microns.

23. The process of claim 20 further comprising:
rotating said substrate during said DC sputter depositing; and
rotating said substrate during said Co-sputter depositing.

24. The process of claim 20, wherein said conductive metal ions are selected from the group consisting of Cu, Ag, Au, Pt and Pd.

25. The process of claim 20, said delafossite metal oxide having the formula ABₓO_{y}
wherein A is a monovalent metal having a metal source selected from the group consisting of Cu, Ag, Au, Pt, and Pd,
wherein B is a trivalent metal having a metal source selected from the group consisting of Al, Ti, Cr, Co, Fe, Ni, Cs, Rh, Ga, Sn, In, Y, La, Pr, Nd, Sm, and Eu,
wherein x has a value from 0.25 to 4, and
wherein y has a value from 0.25 to 4.

26. The process of claim 20, said DC-sputter depositing having a deposition rate between 0.1 Å per second and 1.0 Å per second.

27. The process of claim 20, said Co-sputter depositing having a deposition rate between 0.5 Å per second and 5.0 Å per second.

28. The process of claim 25, said at least one target comprising three targets, wherein said three targets comprises:
one of said monovalent metals; and
two of said trivalent metals.
